(19) United States
(12) Patent Application Publication
(10) Pub. No.: US 2025/0226334 A1
(43) Pub. Date: Jul. 10, 2025

(54) Semiconductor Device and Method of Making a Molded IPD-CoW

(71) Applicant: STATS ChipPAC Pte. Ltd., Singapore (SG)

(72) Inventors: Kai Chong Chan, Singapore (SG); Linda Pei Ee Chua, Singapore (SG); Yaojian Lin, Jiangyin (CN)

(73) Assignee: STATS ChipPAC Pte. Ltd., Singapore (SG)

(21) Appl. No.: 18/406,924

(22) Filed: Jan. 8, 2024

(51) Int. Cl. H01L 23/552; H01L 21/56; H01L 23/00; H01L 25/00; H01L 25/16; H01L 25/18

(52) U.S. Cl. CPC H01L 23/552; H01L 21/561; H01L 21/568; H01L 24/94; H01L 24/97; H01L 25/16; H01L 25/18; H01L 25/50; H01L 24/05; H01L 24/11; H01L 24/13; H01L 24/16; H01L 24/24; H01L 24/81; H01L 2224/0557; H01L 2224/05611; H01L 2224/05624; H01L 2224/05639; H01L 2224/05644; H01L 2224/05647; H01L 2224/05655; H01L 2224/1132; H01L 2224/1145; H01L 2224/11462; H01L 2224/11464; H01L 2224/1184; H01L 2224/13082; H01L 2224/13111; H01L 2224/13113; H01L 2224/13116; H01L 2224/13124; H01L 2224/13139; H01L 2224/13144; H01L 2224/13147; H01L 2224/13155; H01L 2224/16145; H01L 2224/16227; H01L 2224/24101; H01L 2224/24155; H01L 2224/81815; H01L 2224/94; H01L 2224/97; H01L 2924/014

(57) ABSTRACT

A semiconductor device has an integrated passive device (IPD) wafer including an IPD formed on the IPD wafer. A semiconductor die is mounted on the IPD wafer. An interconnect structure is mounted on the IPD wafer. The IPD wafer is singulated to provide an IPD die with the IPD, semiconductor die, and interconnect structure. An encapsulant is deposited over the IPD die with the interconnect structure exposed from the encapsulant. A shielding layer is formed over the encapsulant.

### FIELD OF THE INVENTION

The present invention relates in general to semiconductor devices and, more particularly, to a semiconductor device and method of making molded integrated-passive device (IPD) chip-on-wafer (CoW) devices or modules.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor device manufacturers are continually striving to make smaller semiconductor devices to meet the demands of electronic device manufacturers and consumers alike. When multiple die are to be packaged together, one method of shrinking the end device is to mount the smaller die directly on the semiconductor wafer of the larger die. This is known as chip-on-wafer (CoW). However, the state of the art for CoW devices lacks in many important aspects. Therefore, a need exists for improved CoW devices.

### BRIEF DESCRIPTION OF THE DRAWINGS

FIGS. 1a-1c illustrate a semiconductor wafer with a plurality of semiconductor die separated by a saw street;

FIGS. 2a-2k illustrate forming CoW devices with the semiconductor die on an IPD wafer;

FIG. 3 illustrates a completed CoW device;

FIGS. 4a and 4b illustrate an embodiment using laser-drilling to expose solder bumps through encapsulant;

FIGS. 5a and 5b illustrate an embodiment with embedded conductive pillars;

FIGS. 6a and 6b illustrate an embodiment with embedded PCB units;

FIGS. 7a and 7b illustrate grounding through an external interconnect;

FIGS. 8a and 8b illustrate a backside RDL plane with mesh degassing holes for EMI; and

FIGS. 9a and 9b illustrate an electronic device with the CoW devices.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

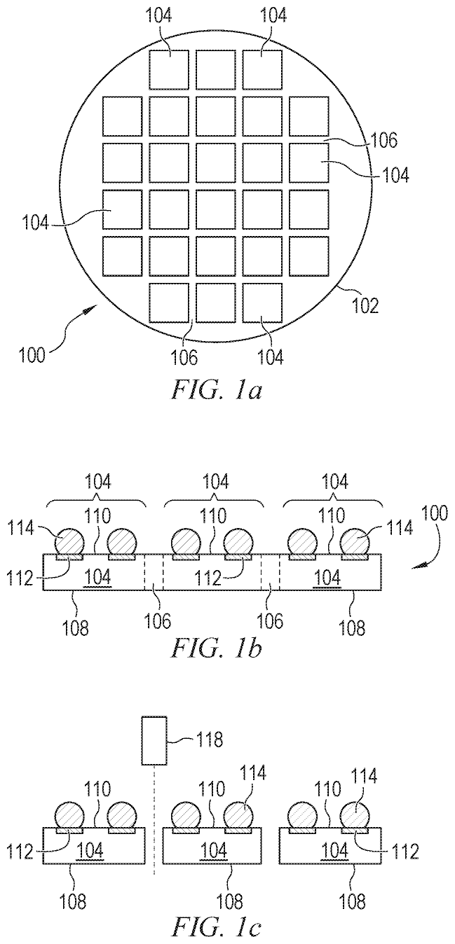

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as a digital signal processor (DSP), application specific integrated circuit (ASIC), memory, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating, sputtering, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under-bump metallization (UBM) having a wetting layer, barrier layer, and adhesive layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 1c, semiconductor wafer 100 is singulated through saw street 106 using a saw blade or laser cutting tool 119 into individual semiconductor die 104. The individual semiconductor die 104 can be inspected and electrically tested for identification of known good die or unit after singulation.

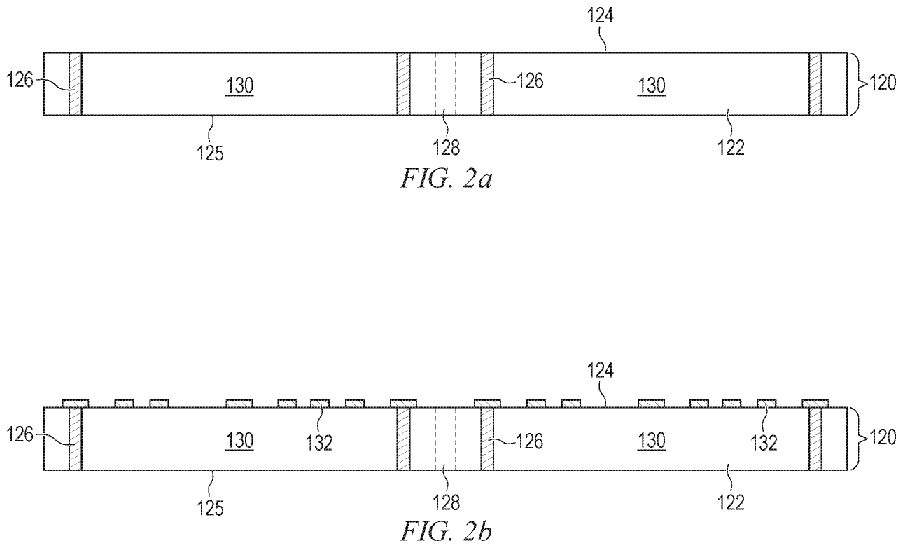

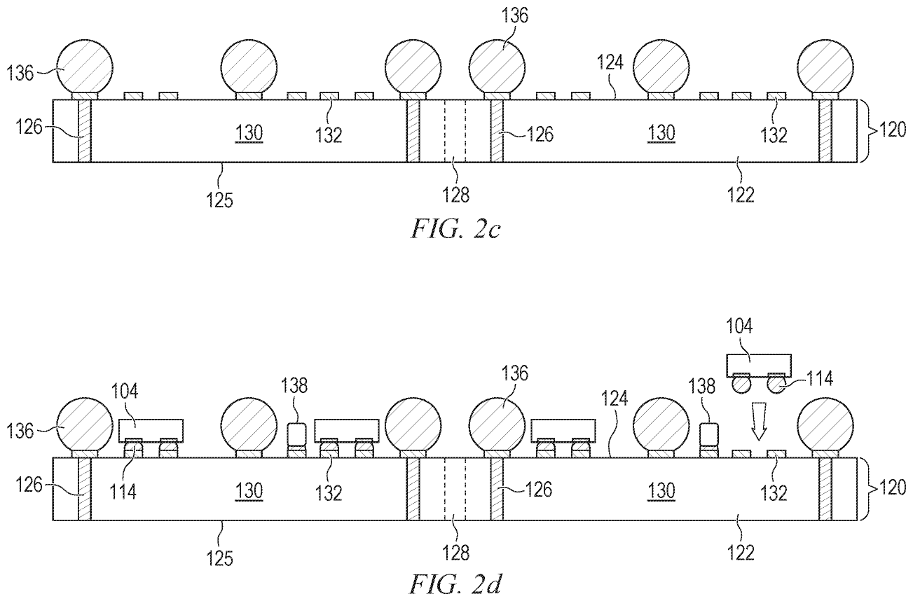

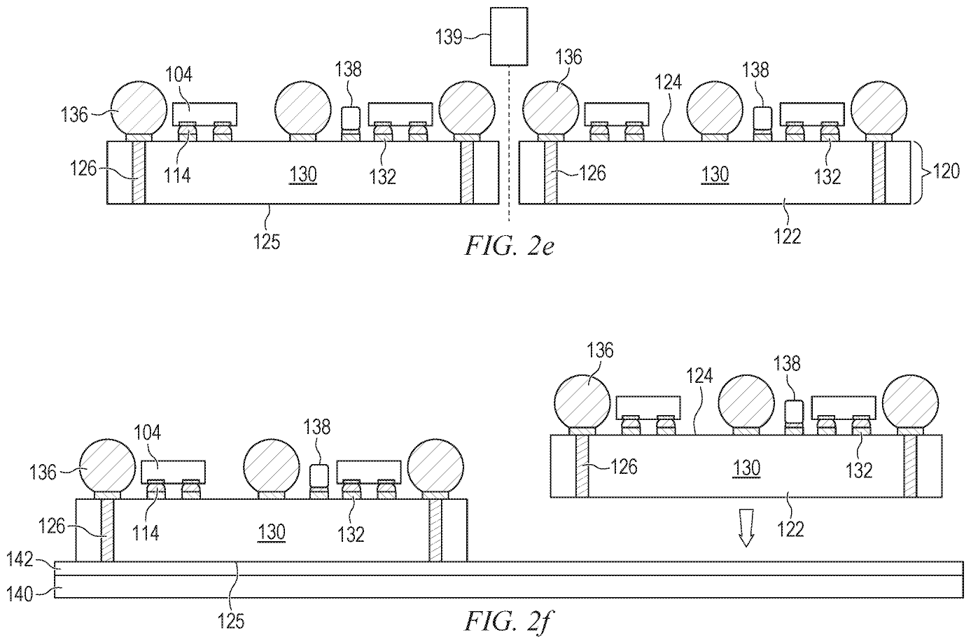

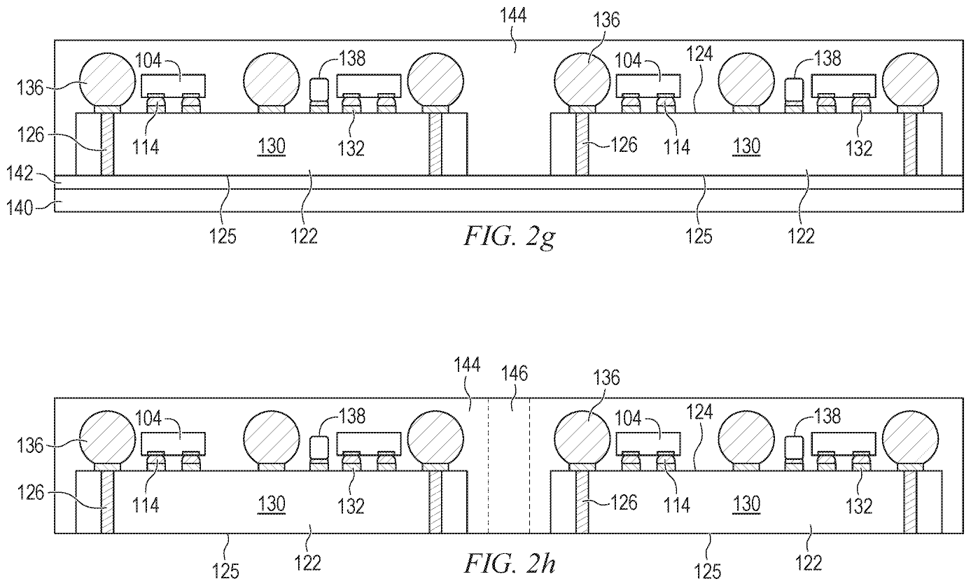

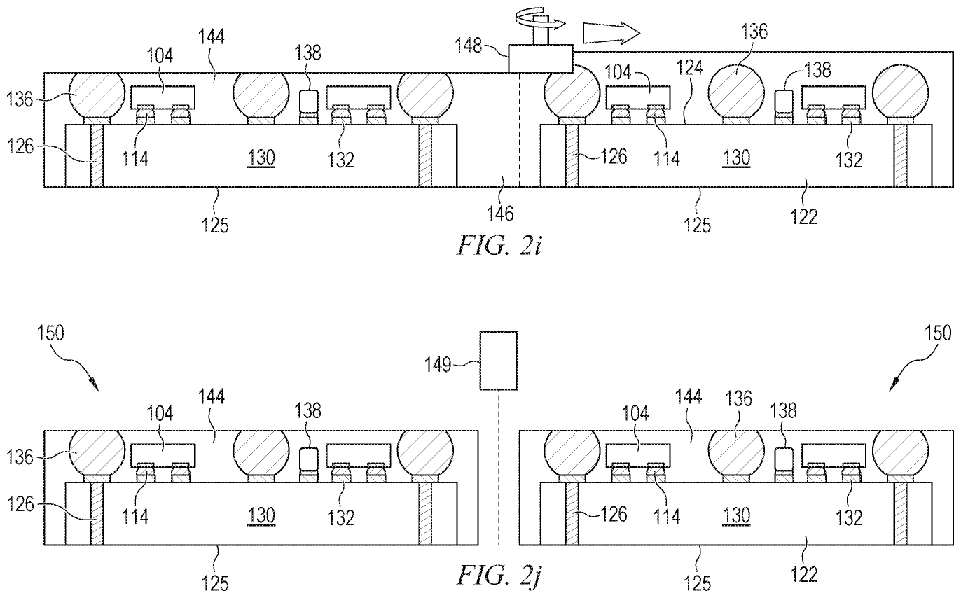

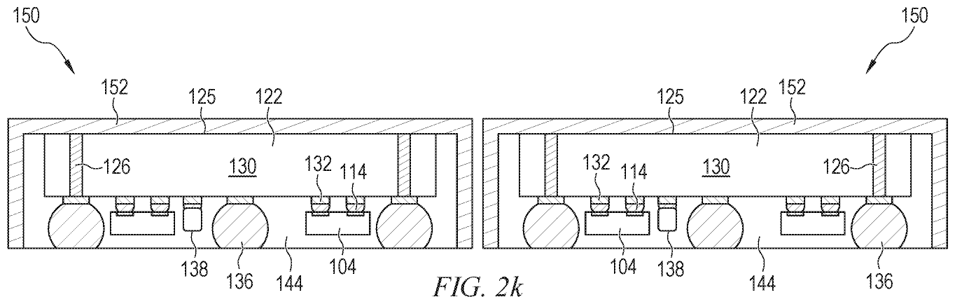

FIGS. 2a-2k illustrate a process of forming a chip-on-wafer (CoW) device with semiconductor die 104 as the chip on an integrated passive device (IPD) wafer 120. FIG. 2a shows a partial cross-section IPD wafer 120. IPD wafer 120 is similar to wafer 100, including usually being formed of bulk semiconductor material 122. Silicon is most commonly used for IPD wafers because the manufacturing equipment used to form IPDs over the wafer is already configured to process silicon wafers. However, other embodiments use wafers of other materials, such as polymers, glass, metal, or other semiconductors. Any suitable substrate material is used in other embodiments.

Wafer 120 includes an active surface 124 with IPDs formed over the active surface prior to the step shown in FIG. 2a. IPDs are optionally formed over back surface 125 as well. IPDs are formed by successively applying and patterning conductive and insulating layers to form the shapes and structures required for the desired IPDs. For instance, conductive structures can be shaped into coils to form inductors or fingers and plates to form capacitors. Resistors can be formed by artificially increasing the lengths of traces or by using different materials with increased electrical resistance. Any suitable passive device or combination of passive devices can be formed on active surface 124 and electrically interconnected to perform the desired electrical function, e.g., a radio frequency (RF) filter. IPD wafer 120 optionally also has active devices formed in active surface 124, but more commonly semiconductor die 104 is relied upon for active electrical functionality while the IPD wafer only provides passive electrical components.

Conductive vias 126 are formed through IPD wafer 120 to provide electrical connection between active surface 124 and back surface 125. Conductive vias 126 are formed by drilling through wafer 120, e.g., using chemical etching, laser drilling, mechanical drilling, or another suitable process, and filling the resulting opening by sputtering, plating, or otherwise depositing a conductive material into the opening. Conductive via 126 can be formed only partially through IPD wafer 120 and then exposed by backgrinding the IPD wafer.

While only two IPD die 130 are shown as being formed in IPD wafer 120, the IPD wafer is usually large enough to form tens or hundreds of units in the IPD wafer to be processed together. IPD die 130 are each surrounded and separated from adjacent IPD die by saw streets 128. IPD wafer 120 will be singulated through saw streets 128 to separate IPD die 130 into individual CoW devices.

In FIG. 2b, a conductive layer 132 is formed over active surface 124. Conductive layer 132 is formed using any of the materials and process described above for conductive layer 112. Conductive layer 132 is patterned to include contact pads for subsequent electrical interconnect to the underlying IPDs and conductive vias 126, contact pads for mounting of additional electrical components, and, if necessary, conductive traces to fan-in or fan-out electrical connections from the underlying IPDs to the contact pads. Conductive layer 132 may also include conductive traces to interconnect the underlying IPDs of active surface 124 into functional electrical circuits, but typically the same conductive layers used to form the IPDs are used to interconnect them together, or any additional necessary electrical connections would have already been formed by the original manufacturer of the IPD wafers before packaging starts in FIG. 2a.

Solder bumps 136 are formed on contact pads of conductive layer 132 in FIG. 2c. Solder bumps 136 are formed as described above for solder bumps 112. Conductive layer 132 optionally has UBM formed of multiple conductive layers including a wetting layer, barrier layer, and adhesion layer where solder bumps 136 are to be disposed. Other types of interconnect structures are used in other embodiments instead of solder bumps 136.

In FIG. 2d, semiconductor die 104, discrete components 138, and any other desired components are mounted or disposed on contact pads of conductive layer 132. Semiconductor die 104 are picked and placed with solder bumps 114 oriented toward IPD wafer 120. Semiconductor die 104 are placed down with bumps 114 physically contacting conductive layer 132, then the bumps are reflowed to physically and electrically connect semiconductor die 104 to IPD wafer 120.

Discrete components 138 are similarly picked and placed onto conductive layer 132. Solder paste can be printed onto the component or onto conductive layer 132 to provide a robust physical and electrical connection after reflow. Discrete components 138 can be any desired active or passive component. Discrete components 138 are illustrated as two-terminal devices seen head-on, so only one terminal is visible. Discrete components 138 can also have three or more terminals and be of any suitable package type.

One or more semiconductor die 104 can be mounted per CoW device being formed. The semiconductor die 104 can all be identical, or complementary semiconductor die can be used on each CoW device, e.g., a processor and a memory chip. Any number and type of electrical component can be mounted onto IPD wafer 120 to implement the desired electrical functionality.

In FIG. 2e, IPD wafer 120 is singulated through saw streets 128 using a laser or other suitable cutting tool 139 to separate the individual IPD die 130 from each other. In FIG. 2f, the singulated IPD die 130 are picked and placed onto a temporary substrate or carrier 140 with double sided tape or interface layer 142. IPD die 130 are placed with back surfaces 125 on carrier 140, and solder bumps 136 extending upward away from the carrier.

Carrier 140 contains sacrificial base material such as silicon, polymer, beryllium oxide, glass, or other suitable low-cost, rigid material for structural support. An interface layer or double-sided tape 142 is formed or disposed over carrier 140 as a temporary adhesive bonding film, etch-stop layer, thermal release layer, or UV release layer. Carrier 140 can be a round or rectangular panel with capacity for multiple IPD die 130 to be processed at once. While only two IPD die 130 are illustrated, tens, hundreds, or more modules may be processed together on a common carrier 140. In some embodiments, a gap between IPD die 130 on carrier 140 is larger than saw street 128.

In FIG. 2g, encapsulant or molding compound 144 is deposited over and around carrier 140, IPD die 130, solder bumps 136, semiconductor die 104, and discrete components 138 using a paste printing, compressive molding, transfer molding, liquid encapsulant molding, vacuum lamination, spin coating, or another suitable applicator. Encapsulant 144 can be liquid or granular polymer composite material, such as epoxy resin, epoxy acrylate, or polymer, with or without an added filler. In another embodiment, encapsulant 144 is a laminated mold sheet or film with or without fillers. Encapsulant 144 is non-conductive, provides structural support, and environmentally protects IPD die 130 and semiconductor die 104 from external elements and contaminants. Encapsulant 144 completely covers the previously exposed outer surfaces of solder bumps 136. In other embodiments, encapsulant 144 is deposited to have the tops of solder bumps 136 slightly exposed or a top surface of the encapsulant coplanar to the top surfaces of alternative interconnect structures.

Carrier 140 is debonded and removed from the panel of bridge die IPD die 130 and encapsulant 144 in FIG. 2h. The adhesive properties of interface layer 142 are reduced by thermal, ultraviolet, laser, or other energy application in some embodiments before mechanically removing carrier 140 from the panel. The panel in FIG. 2h may be referred to as a reconstituted wafer because, in a sense, IPD wafer 120 has been reconstituted with IPD die 130 further apart than in the IPD wafer, with encapsulant 144 used to hold the die together in a wafer form.

In FIG. 2i, encapsulant 140 is backgrinded using a grinder 148, chemical-mechanical planarization, chemical etching, or another suitable process to reduce a thickness of the encapsulant and thereby expose tops of solder bumps 136. A portion of each bump 136 is removed as well to planarize the bumps and provide for top surfaces of the bumps to be coplanar to encapsulant 144. In FIG. 2j, IPD die 130 are singulated into individual IPD-CoW devices 150 by cutting through encapsulant 144 in saw streets 146 using a laser cutting tool, saw blade, or other suitable tool 149.

After singulation, IPD-CoW devices 150 are flipped and disposed on another or the same carrier, with back surfaces 125 oriented upward or otherwise exposed. To address electromagnetic interference (EMI), radio frequency interference (RFI), harmonic distortion, and other inter-device interference, a shielding layer 152 is formed over back surface 125 of IPD die 130 and top and side surfaces of encapsulant 144. Shielding layer 152 is deposited, printed, sputtered, plated, or otherwise formed. Plating can be performed by CVD, PVD, other sputtering methods, electroplating, electroless plating, or another suitable metal deposition process. Shielding layer 152 includes one or more layers of Al, Ti, Cu, Sn, Ni, Au, Ag, stainless steel, or other suitable electrically conductive material.

Singulating through encapsulant 144 to form individual IPD-CoW devices 150 prior to forming shielding layer 152 allows the shielding layer to be formed down side surfaces of the packages, which is optional but helps to protect from laterally incident EMI. Shielding layer 152 is formed directly on surfaces of conductive vias 126 exposed at back surface 125. Conductive vias 126 and the solder bumps 136 formed over each via allow the shielding layer to be connected to ground, thereby improving shielding performance.

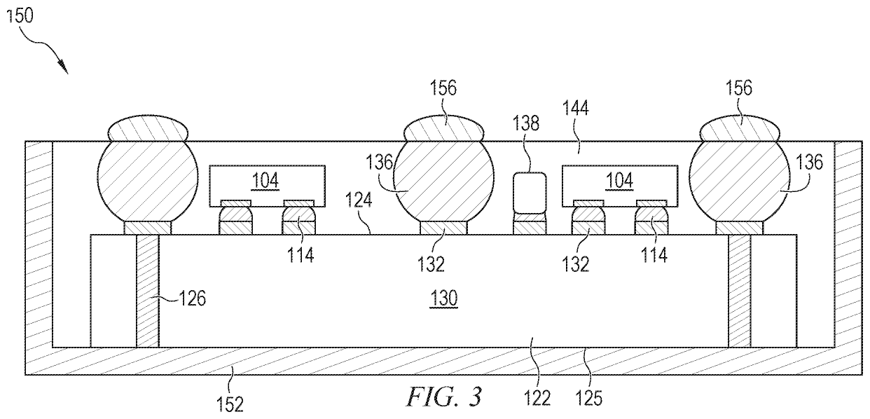

IPD-CoW devices 150 in FIG. 2k are completed semiconductor packages ready to be incorporated into a larger electronic device or stored in a tape-and-reel for delivery to a device manufacturer. Optionally, as shown in FIG. 3, an additional portion of solder paste 156 can be printed or otherwise disposed onto each exposed solder bump 136 to create a composite or compound bump that extends continuously from conductive layer 132 to over the surface of encapsulant 144. Solder paste 156 can be reflowed together with solder bumps 136 during manufacturing. Solder paste 156 extending over encapsulant 144 provides some standoff to make mounting IPD-CoW device 150 to the PCB or substrate of a larger electronic device easier.

IPD-CoW device 150 is a chip-on-wafer device with passive components formed as IPDs on the wafer side of the chip-on-wafer and EMI shielding formed over the package. Additional passive components and semiconductor die are flip-chip or surface-mount attached on IPD die 130. IPD-CoW device 150 can be manufactured with relatively low cost and complexity due to the use of existing fan-out wafer-level package manufacturing equipment.

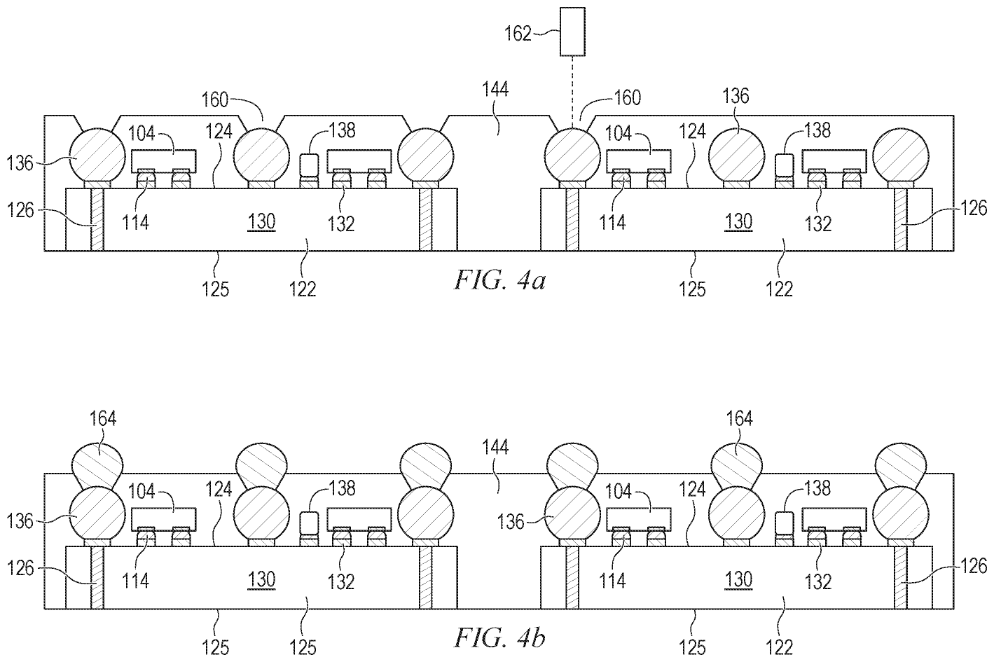

FIGS. 4a and 4b illustrate an alternative embodiment continuing from FIG. 2h. In FIG. 4a, openings 160 are formed through encapsulant 144 to expose solder bumps 136 using a laser 162. Openings 160 can also be formed by chemical etching, mechanical drilling, or another suitable means. In FIG. 4b, additional solder bumps or solder paste 164 is disposed in the openings 160 on each bump 136. Bumps 136 and 164 can optionally be reflowed together at this stage to form a single continuous body of solder. Manufacturing continues as shown in FIGS. 2j and 2k to complete semiconductor packages with solder bumps 164.

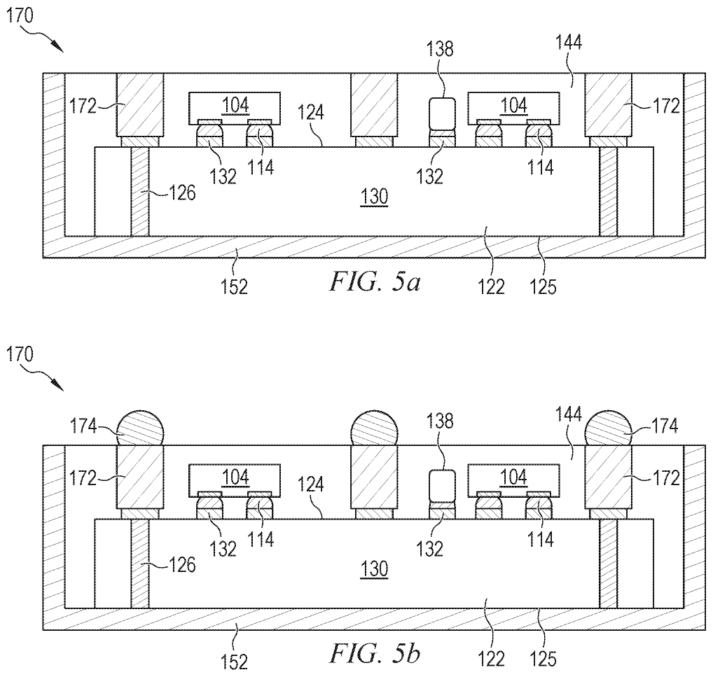

FIGS. 5a and 5b illustrate an alternative embodiment where an IPD-CoW device 170 has solder bumps 136 replaced by conductive pillars 172. Conductive pillars 172 are mounted onto contact pads of conductive layer 132 during the step shown in FIG. 2c, but otherwise the manufacturing process goes as shown in FIGS. 2a-2k. Conductive pillars 172 can be formed separately and then attached to conductive layer 132 by a thin layer of solder. Alternatively, conductive pillars 172 can be grown on or as part of conductive layer 132 by plating or another suitable process. Encapsulant 144 is optionally deposited coplanar to conductive pillars 172 by film-assisted molding or another suitable process rather than being backgrinded as shown in FIG. 2i. Solder bumps 174 are formed on conductive pillars 172 in FIG. 5b as described above for bumps 114 on conductive layer 112. Solder bumps 136 can be replaced by conductive pillars 172 in any of the above or below embodiments.

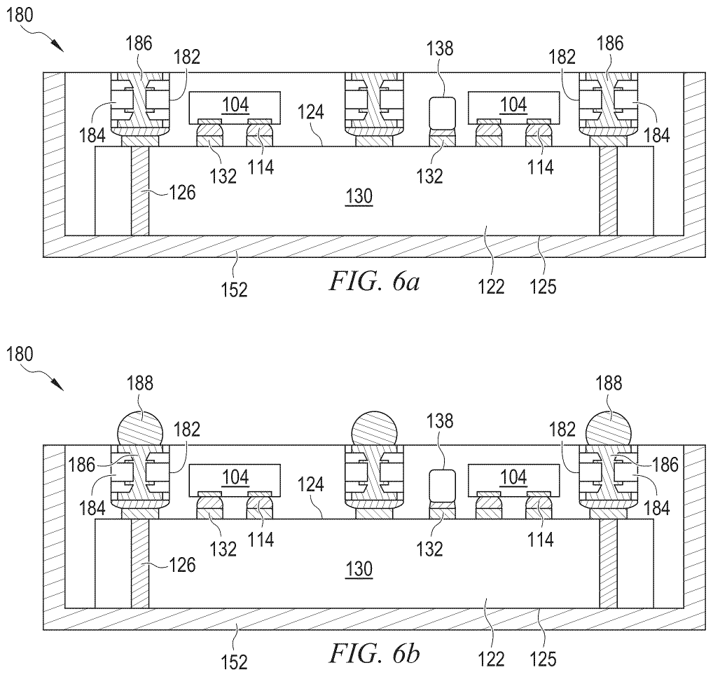

FIGS. 6a and 6b show a similar embodiment, but with IPD-CoW device 180 having PCB units 182 instead of conductive pillars 172. PCB units 182 are essentially small PCBs, having one or more insulating layers 184 stacked with one or more conductive layers 186. Insulating layers 184 can include a core insulating board and additional insulating layers deposited over the core board. Conductive layers 186 can include conductive vias formed through insulating layers 184 and contact pads formed on the insulating layers. While usually exclusively vertically oriented, some PCB units 182 may have lateral conductive traces for electrical interconnect.

PCB units 182 may have only a single electrical contact coupled to one contact pad of conductive layer 132, or a single PCB unit may extend for a length having one or more rows or columns of contacts. PCB units 182 are mounted to contact pads of conductive layer 132 using a solder or solder paste prior to deposition of encapsulant 144. Solder bumps 188 are mounted on the exposed contacts of PCB units 182 in FIG. 6b as described above for solder bumps 114. Solder bumps 136 and conductive pillars 172 can be replaced by PCB units 182 in any of the above or below embodiments.

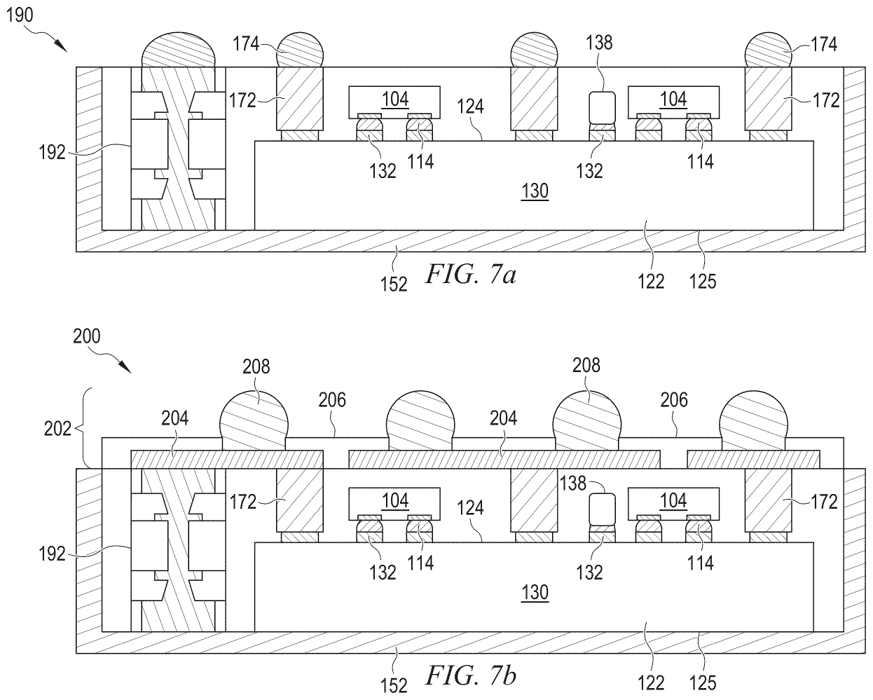

FIGS. 7a and 7b illustrate an embodiment with a PCB unit used to ground shielding layer 152 as an alternative to grounding through conductive vias 126. FIG. 7a shows an IPD-CoW device 190. IPD die 130 is formed without conductive vias 126. To provide grounding to shielding layer 152, a PCB unit 192 is disposed on carrier 140 along with CoW die 130 during the step shown in FIG. 2f. In one embodiment, PCB unit 192 has a plurality of contacts along a length of IPD die 130 and is placed along one or more sides of IPD die 130. In another embodiment, a plurality of individual-contact PCB units can be placed along one or more sides of IPD die 130. A conductive bar or pillar can be used instead of PCB units.

PCB unit 192 is formed and structured as described above for PCB units 182. Encapsulant 144 is deposited over both IPD die 130 and PCB unit 192 during the step shown in FIG. 2g. Manufacturing otherwise goes as described above. Conductive pillars 172 are illustrated, but solder bumps 136 or PCB units 182 can be used instead.

FIG. 7b shows a similar embodiment but with an interconnect structure 202 formed over IPD-CoW device 200. Interconnect structure 202 includes a conductive layer 204 formed on PCB unit 192, conductive pillars 172, and encapsulant 144. Conductive layer 204 includes contact pads on the exposed conductive structures and at locations where solder bumps 208 are to be formed. Conductive traces of conductive layer 204 interconnect the contact pads as desired, e.g., by distributing a single electrical connection to ground to both PCB unit 192 and IPD die 130.

A solder resist, passivation, or insulating layer 206 is formed over conductive layer 204. Insulating layer 206, and any insulating layer mentioned above or below, can be formed using PVD, CVD, printing, lamination, spin coating, spray coating, sintering or thermal oxidation, and contains one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. A portion of insulating layer 206 is removed using an etching process or laser direct ablation (LDA) to expose conductive layer 204. Solder bumps 208 are formed on conductive layer 204 in the openings of insulating layer 206 as described above for solder bumps 114.

Interconnect structure 202 can be referred to as a build-up interconnect structure because the interconnect structure is formed by building up layer-after-layer of alternating insulating and conductive layers. The routing of interconnect structure 202 can be made more complex by stacking multiple interconnected conductive layers interleaved between insulating layers.

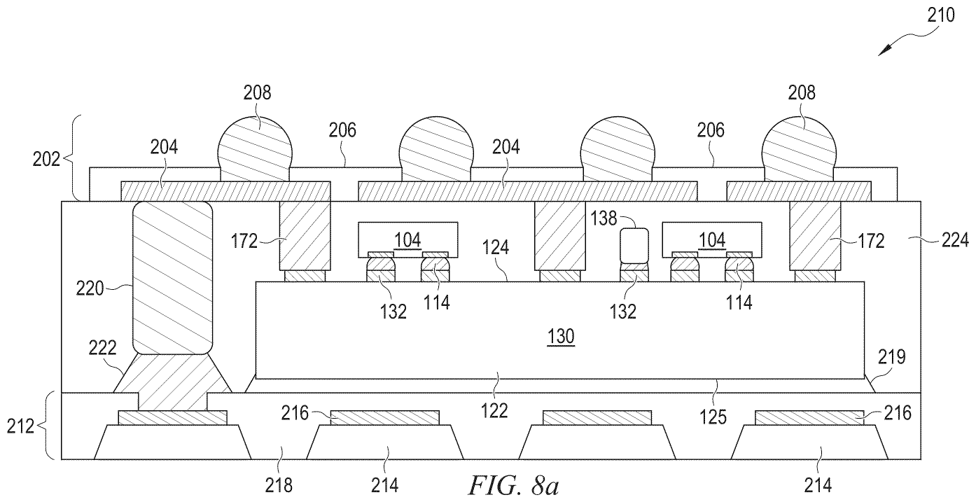

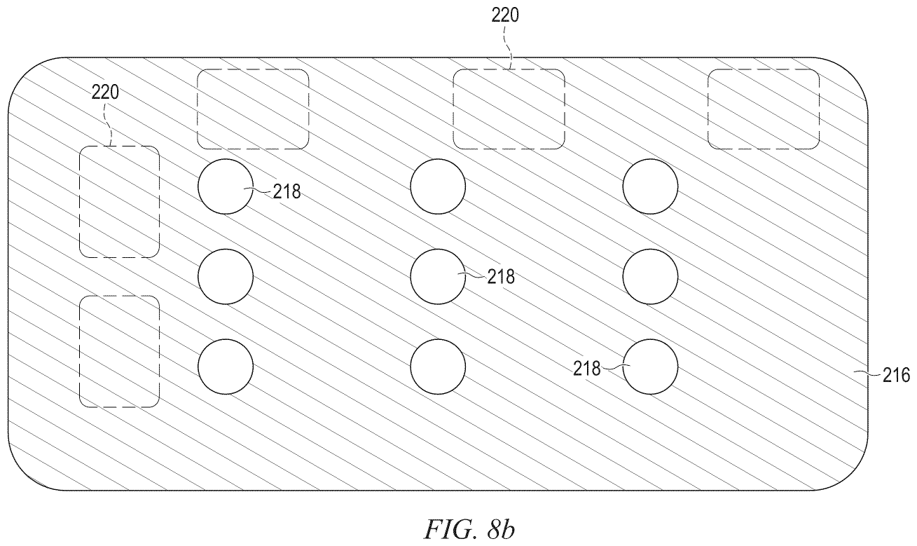

FIGS. 8a and 8b illustrate an embodiment with a backside embedded grounding plane 212. Backside embedded grounding plane 212 can be formed on a carrier. An insulating support layer 214 is first deposited and patterned. Insulating support layer 214 is formed of materials and using the processes described above for insulating layers generally. A conductive ground plane 216 is formed on insulating support layer 214. Conductive ground plane 216 includes a plurality of openings under IPD die 130 as mesh degassing holes where insulating layer 218 is visible in the plan view of FIG. 8b. Conductive ground plane 216 is formed as described above for conductive layers. In one embodiment, ground plane 216 is formed of a Ti layer and a Cu layer, with an optional NiFe layer formed over the Cu layer. Any suitable conductive shielding material can be used in other embodiments.

A conductive bar 220 is mounted onto backside embedded grounding plane 212 using solder 222. Conductive bar 220 can be a single cylindrical bar oriented vertically or may extend continuously or in multiple discrete portions along one or more sides of IPD die 130. Interconnect structure 202 or bumps 174 are formed on conductive bar 220 and pillars 172.

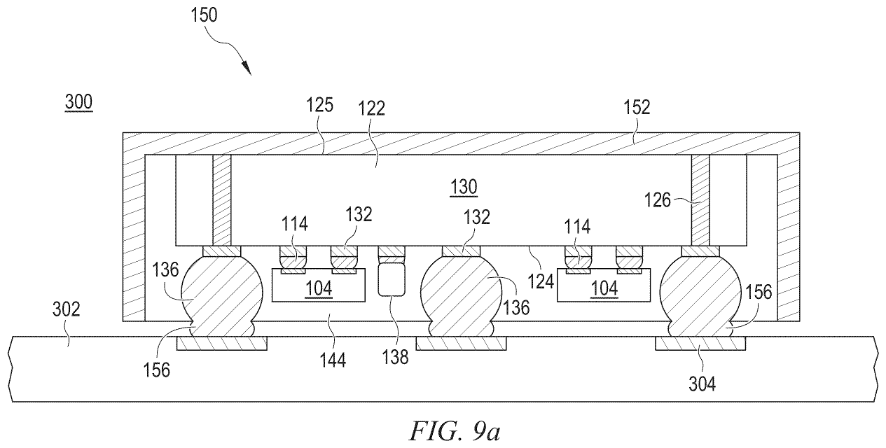

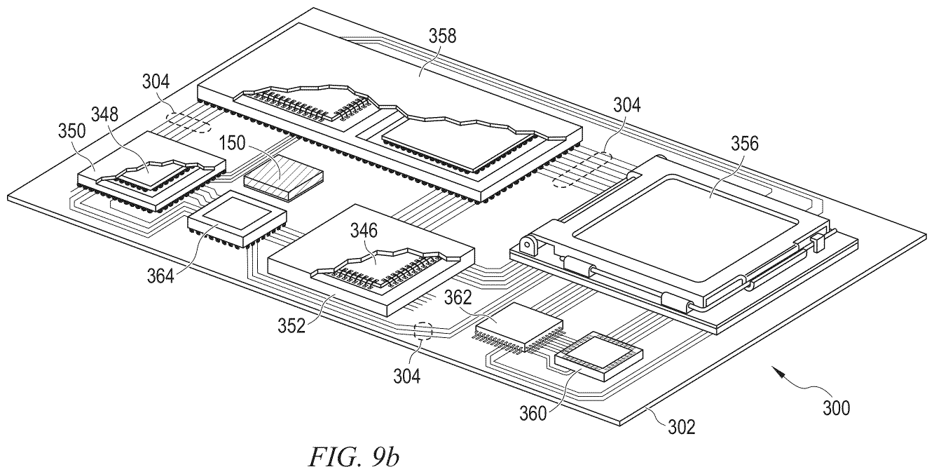

FIGS. 9a and 9b illustrate integrating the above-described semiconductor packages, e.g., IPD-CoW device 150, into a larger electronic device 300. FIG. 7a illustrates a partial cross-section of IPD-CoW device 150 mounted onto a printed circuit board (PCB) or other substrate 302 as part of electronic device 300. Bumps 136 and 156 are reflowed together and onto conductive layer 304 of PCB 302 to physically attach and electrically connect IPD-CoW device 150 to the PCB. In other embodiments, thermocompression or another suitable attachment and connection methods are used. In some embodiments, an adhesive or underfill layer is used between IPD-CoW device 150 and PCB 302. Semiconductor die 104 and IPD die 130 are electrically coupled to conductive layer 304 through bumps 136/156 and conductive layer 132.

FIG. 7b illustrates electronic device 300 having a chip carrier substrate or PCB 302 with a plurality of semiconductor packages disposed on a surface of PCB 302, including IPD-CoW device 150. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 7b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing an integrated passive device (IPD) wafer including an IPD formed on the IPD wafer;
mounting a semiconductor die on the IPD wafer;
mounting an interconnect structure on the IPD wafer;
singulating the IPD wafer to provide an IPD die with the IPD, semiconductor die, and interconnect structure;
depositing an encapsulant over the IPD die with the interconnect structure exposed from the encapsulant; and
forming a shielding layer over the encapsulant.

2. The method of claim 1, further including:
disposing a second interconnect structure adjacent to the IPD die; and
depositing the encapsulant over the IPD die and second interconnect structure.

3. The method of claim 1, further including forming a build-up interconnect structure over the IPD die and encapsulant.

4. The method of claim 1, wherein the IPD die includes a conductive via formed through the IPD die.

5. The method of claim 1, further including forming the shielding layer as an embedded backside RDL plane with a plurality of mesh degassing holes.

6. The method of claim 1, further including depositing a solder or solder paste over the interconnect structure after depositing the encapsulant.

7. A method of making a semiconductor device, comprising:
providing an integrated passive device (IPD) wafer;
mounting a semiconductor die on the IPD wafer;
singulating the IPD wafer to provide an IPD die;
depositing an encapsulant over the IPD die; and
forming a shielding layer over the encapsulant.

8. The method of claim 7, further including:
disposing an interconnect structure adjacent to the IPD die; and
depositing the encapsulant over the IPD die and interconnect structure.

9. The method of claim 7, further including forming a build-up interconnect structure over the IPD die and encapsulant.

10. The method of claim 7, wherein the IPD die includes a conductive via formed through the IPD die.

11. The method of claim 7, further including:
disposing an interconnect structure over the IPD die;
depositing the encapsulant over the interconnect structure; and
depositing a solder or solder paste over the interconnect structure after depositing the encapsulant.

12. The method of claim 11, further including:
depositing the encapsulant to fully cover the interconnect structure; and
removing a portion of the encapsulant to expose the interconnect structure.

13. The method of claim 7, further including forming the shielding layer as an embedded backside RDL plane.

14. A semiconductor device, comprising:
an integrated passive device (IPD) die including an IPD formed on the IPD die;
a semiconductor die mounted on the IPD die;
an interconnect structure mounted on the IPD die;
an encapsulant deposited over the IPD die with the interconnect structure exposed from the encapsulant; and
a shielding layer formed over the encapsulant.

15. The semiconductor device of claim 14, further including a second interconnect structure disposed adjacent to the IPD die, wherein the encapsulant is deposited over the IPD die and second interconnect structure.

16. The semiconductor device of claim 14, further including a build-up interconnect structure formed over the IPD die and encapsulant.

17. The semiconductor device of claim 14, wherein the IPD die includes a conductive via formed through the IPD die.

18. The semiconductor device of claim 14, wherein the shielding layer includes an embedded backside RDL plane.

19. The semiconductor device of claim 14, further including a solder or solder paste deposited over the interconnect structure.

20. A semiconductor device, comprising:
an integrated passive device (IPD) die;
a semiconductor die mounted on the IPD die;
an encapsulant deposited over the IPD die; and
a shielding layer formed over the encapsulant.

21. The semiconductor device of claim 20, further including an interconnect structure disposed adjacent to the IPD die, wherein the encapsulant is deposited over the IPD die and interconnect structure.

22. The semiconductor device of claim 20, further including a build-up interconnect structure formed over the IPD die and encapsulant.

23. The semiconductor device of claim 20, wherein the IPD die includes a conductive via formed through the IPD die.

24. The semiconductor device of claim 20, further including:
an interconnect structure disposed over the IPD die; and
a solder or solder paste disposed over the interconnect structure.

25. The semiconductor device of claim 20, wherein the shielding layer includes a backside RDL plane.
